(19) United States
(12) Patent Application Publication
(10) Pub. No.: US 2013/0025916 A1
(43) Pub. Date: Jan. 31, 2013

(54) FLAME RETARDANT EPOXY LAMINATE CONTAINING METAL PHOSPHONATE

(71) Applicants: Sergei V. Levchik, Croton-on-Hudson, NY (US); Anantha Desikan, Yorktown Heights, NY (US)

(72) Inventors: Sergei V. Levchik, Croton-on-Hudson, NY (US); Anantha Desikan, Yorktown Heights, NY (US)

(73) Assignee: ICL-IP America Inc., Ardsley, NY (US)

(21) Appl. No.: 13/360,177

(22) Filed: Jan. 27, 2012

Related U.S. Application Data
(60) Provisional application No. 61/444,185, filed on Feb. 18, 2011.

(51) Int. Cl. B32B 27/38; H05K 1/09; B32B 27/12

(52) U.S. Cl. 174/257; 428/413; 428/221

(57) ABSTRACT

There is provided herein an epoxy laminate comprising (a) an epoxy resin composition further comprising (i) at least one curable epoxy resin, (ii) at least one curing agent, (iii) at least one curing catalyst; and, (iv) a flame retardant effective amount of at least one metal phosphonate represented by the general formula:

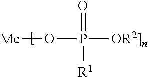

where Me is a metal, n is equal to the valency of the metal which is in the range of from 1 to 4, R¹ is a linear or branched alkyl of up to about 12 carbon atoms, R² is a linear or branched alkyl of up to about 12 carbon atoms or a substituted aryl or unsubstituted aryl of general formula:

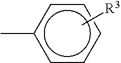

where R³ hydrogen, or a branched or linear alkyl of up to about 4 carbon atoms, or NH₂ or CN or NO₂,
(b) a reinforcing material; and, (c) a copper foil.

### FIELD OF THE INVENTION

This invention relates to an epoxy laminate, in particular a flame retarded epoxy laminate comprising a curable epoxy resin composition. The flame retarded epoxy resin composition is halogen-free, and it can provide high glass transition temperature and good hydrolytic stability to the flame retarded epoxy laminate.

### DETAILED DESCRIPTION OF THE RELATED ART

Flame retardant epoxy resins are used in a variety of electrical insulating materials due to the excellent self-extinguishing property, mechanical property, water-vapor resistance and electrical property. In the preparation of epoxy laminates various additives can be incorporated into the epoxy resin composition to provide flame-retardancy to the resulting laminate. While flame retardants for laminates do exist such flame retardants are halogen-containing flame retardants, such as tetrabromobisphenol A, or epoxy resins prepared with tetrabromobisphenol A.

Although halogen-containing flame-retardants such as tetrabromodiphenylolpropane provide flame retardancy, such flame retardants are considered by some to be undesirable from an environmental standpoint, and in recent years there has been increasing interest in procuring a halogen-free epoxy resin, which is able to meet a V-1 or V-0 flame retardancy requirement in the standard “Underwriters Laboratory” test method UL 94.

While some commercially available phosphorus-based flame retardant additives may be used to replace halogen-containing flame-retardants, such as addition-type phosphorus system flame-retardants, phosphate esters such as these tend to absorb moisture which leads to a poor solder heat resistance (pressure cooker test, PCT) and poor resistance to chemicals, e.g., poor alkali resistance. In addition, because of a significant plasticizing effect of these phosphorus additives the glass transition temperature (T_{g}) of the cured epoxy resin containing such flame retardants also finds a significant drop. Some examples of such addition-type phosphorus system flame-retardants are those such as triphenyl phosphate (TPP), tricresyl phosphate (TCP), cresyldiphenyl phosphate (CDP), resorcinol bis(diphenyl phosphate) (RDP), bisphenol A bis(diphenyl phosphate) (BDP) and the like.

Alkyl and aryl phosphonates in general can also function as flame retardants for epoxy resins. In particular lower alkyl phosphonates can be used because they contain a high proportion of phosphorus. Although phosphonates are more hydrolytically stable then phosphates they still suffer similar problems such as those described above for phosphates. The main problems with phosphonates are low glass transition temperature and high moisture absorption of epoxy compounds. Laminates containing high levels of moisture tend to blister and fail when introduced to a bath of liquid solder at temperatures around 260° C. for lead-based solder, or around 288° C. for lead-free solder, a typical step in the manufacture of printed wiring boards.

It would be desirable to provide a halogen-free flame retardant epoxy resin composition for use in the production of epoxy prepregs and epoxy laminates and in the manufacture of printed-wiring boards and multilayer printed-wiring boards, which halogen-free flame retardant epoxy resin composition possesses high thermal stability and good moisture resistance.

### SUMMARY OF THE INVENTION

The present invention provides an epoxy laminate comprising (a) an epoxy resin composition further comprising (i) at least one curable epoxy resin, (ii) at least one curing agent, e (iii) at least one curing catalyst; and, (iv) a flame retardant effective amount of at least one metal phosphonate represented by the general formula:

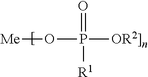

where Me is a metal, n is equal to the valency of the metal which is in the range of from 1 to 4, preferably 2 or 3, R¹ is a linear or branched alkyl of up to about 12 carbon atoms, preferably from 1 to about 4 carbon atoms, R² is a linear or branched alkyl of from 1 to about 12 carbon atoms or a substituted aryl or unsubstituted aryl of general formula:

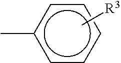

where R³ hydrogen, or a branched or linear alkyl of from up to about 4 carbon atoms, or NH₂ or CN or NO₂,
(b) a reinforcing material; and, (c) a copper foil.

The present invention also relates to articles such as printed wiring boards, e.g., printed wiring boards for electronic applications that are manufactured from the herein described flame retardant epoxy resin laminate.

### DESCRIPTION OF THE PREFERRED EMBODIMENTS

The epoxy resin composition (a) described herein contains, (i) at least one epoxy resin, preferably a curable epoxy resin. This component can be a non-halogen containing epoxy resin, for example, monofunctional epoxies, aliphatic, cycloaliphatic, and aromatic monofunctional epoxy resins and includes such chemistries as cresyl glycidyl ether, benzyl glycidyl ether. Other useful epoxy resins of the present invention include, but are not limited, to difunctional, trifunctional, tetrafunctional, and higher functional epoxy resins. Examples of these types of epoxies include, but are not limited to diglycidyl ethers of bisphenol A, diglycidyl ethers of bisphenol F, diglycidyl ether of bisphenol S, diglycidyl-p-aminophenol, triglycidyl aminocresol, triglycidyl-p-aminophenol, tetraglycidyl ethers of methylenedianiline, phenol novolac type epoxy resins, cresol novolac type epoxy resins, resorcinol type epoxy resins, epoxy resins with a naphthalene skeleton, biphenyl type epoxy resins, dicyclopentadiene type epoxy resins and diphenylfluorene type epoxy resins, and the like. These resins can be used individually or in any appropriate combination. Also, other useful epoxy resins or other resins of this general type that are useful in the present invention are those that have utility for the manufacture of printed wiring boards or other electronic substrate materials. As such, compatible mixtures of any of these resins may be employed, if desired.

In one specific embodiment, the epoxy resin of the epoxy resin composition can be a non-phosphorus epoxy resin, more specifically an epoxy resin that does not contain any aromatic phosphate ester moieties in the main resin chain. In one other example, the epoxy resin composition of the epoxy laminate is in the absence of unreactive phosphorus-containing component, other than the metal phosphonate

This component, i.e., the (i) epoxy resin, is present in an amount that ranges from about 40 to about 90 percent by weight of the total weight of the epoxy resin composition (a). More preferably, the epoxy resin is present in an amount that ranges from about 60 to about 80 percent by weight of the total weight of the epoxy resin composition.

The curing agent component (ii) useful in the present invention may be any compound having an active group being reactive with the epoxy group of the epoxy resin. The curing agent useful in the present invention includes nitrogen-containing compounds such as amines and their derivatives; oxygen-containing compounds such as carboxylic acid terminated polyesters, anhydrides, phenol-formaldehyde resins, amino-formaldehyde resins, phenol, bisphenol A and cresol novolacs, phenolic-terminated epoxy resins; sulfur-containing compounds such as polysulfides, polymercaptans; and catalytic curing agents such tertiary amines, Lewis acids, Lewis bases and combinations of those curing agents.

Most specifically, polyamines, dicyandiamide, diaminodiphenylsulfone and their isomers, aminobenzoates, various acid anhydrides, phenol-novolac resins and cresol novolac resins, for example, may be used in the present invention, but the present disclosure is not restricted to the use of these compounds.

The curing agent (ii) is present in the amount that ranges from about 3 to about 30 percent by weight of the total weight of the epoxy resin composition (a). Preferably, the curing agent is present in an amount that ranges from about 5 to about 20 percent by weight of the total weight of the composition.

In addition to the epoxy resin and curing agent, the epoxy resin composition of the present disclosure includes (iii) at least one catalyst. Catalysts useful in the present invention are those catalysts which catalyze the reaction of epoxy resin with a curing agent and may be selected from alkaline metal compounds, alkaline earth metal compounds, imidazole compounds, secondary amine compounds, tertiary amine compounds, quaternary ammonium salts and quaternary phosphonium salts.

The inmidazole compounds may include imidazole, 2-ethylimidazole, 2-ethyl-4-imidazole, 2-phenylimidazole, 2-undecylimidazole, 1-benzyl-2-methylimidazole, 2-heptadecylimidazole, 4,5-diphenylimidazole, 2-methylimidazoline, 2-phenylimidazoline, 2-undecylimidazoline, 2-heptadecylimidazoline, 2-isopropylimidazole, 2,4-dimethylimidazole, 2-phenyl-4-methylimidazole, 2-ethylimidazoline, 2-isopropylimidazoline, 2,4-dimethylimidazoline, and 2-phenyl-4-methylimidazoline. Any number of such curing agents may be used in combination.

The amount of the catalyst (iii) that is to be added to 100 weight parts of epoxy resin composition including epoxy resin, curing catalyst and metal phosphonate should be in the range of from about 0.01 to about 5 weight parts (p.h.r.), more preferable in the range of from about 0.05 to about 1.0 p.h.r.

As described above, the metal phosphonate (iv) used herein can be a metal phosphonate (salt of alkyl alkylphosphonic acid or aryl alkylphosphonic acid represented by general formula (I):

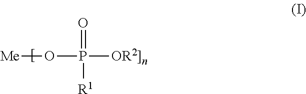

where Me is a metal, n is equal to the valency of the metal which is in the range of from 1 to 4, preferably 2 or 3, R¹ is a linear or branched alkyl of up to about 12 carbon atoms, preferably from 1 to about 4 carbon atoms, R² is a linear or branched alkyl of up to about 12 carbon atoms or a substituted aryl or an unsubstituted aryl of general formula (II):

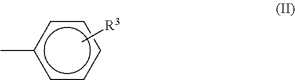

where R³ hydrogen, or a branched or linear alkyl of up to about 4 carbon atoms, or NH₂ or CN or NO₂.

Metals, i.e., Me of the above formula, which can be present in the metal phosphonate (I) include alkaline earth or transition metals such as the non-limiting group consisting of Ca, Mg, Zn, Al, Fe, Ni, Cr, Ti.

In one embodiment the metal phosphinate is an aluminum salt of methyl methylphosphonic acid (AMMP), where Me is aluminum, R¹ and R² are both methyl and n=3. AMMP contains a high level (i.e., 26 weight percent) of active phosphorus. AMMP can be synthesized either by reacting methyl methylphosphonate with an aqueous solution of sodium hydroxide followed by precipitation with aluminum chloride, or by direct reaction of aluminum hydroxide with methyl methylphosphonate at 180° C. in high shear mixer.

Preferably, the metal phosphonate is a powder with an average particle size of less than about 25 microns, more preferably less than about 10 microns, and even more preferably less than about 5 microns. The preferred metal phosphonate average particle size according to the present embodiments comprises a plurality of particles having an average size in the range of from about 0.1 microns to about 3 microns. It will be understood that any of the aforementioned average particle size ranges can have a lower end point of from about 0.1 microns.

Preferably, the metal phosphonate is present in the flame retardant curable epoxy composition in a flame retardant effective amount, such as for example, the range from about 5 to about 40 wt. % and more preferably in the range from about 15 to about wt. % based on the total weight of the curable epoxy composition.

The epoxy resin composition (a) can optionally include thermoplastic compounds which are useful for improving physical and electrical properties of the cured epoxy resin composition. The curable epoxy resin composition can include thermoplastic compounds having glass transition temperatures (Tg) greater than 120° C., because thermoplastics with lower Tg's have a deleterious effect on the thermal performance of the cured composition. Representative of such preferred thermoplastic compounds include, for example, poly(phenylene ether) compounds, polyimides, and poly(styrene-co-maleic anhydride).

Poly(phenylene ether) compounds are the most preferred thermoplastic compounds for use in the curable epoxy composition and include all known poly(phenylene ether) compounds, poly(phenylene ether) copolymers, and derivatized poly(phenylene ether) resins synthesized therefrom.

Preferred poly(phenylene ether) compounds for use herein include low molecular weight poly(phenylene ether) compounds having number average molecular weights from about 1,000 to about 10,000 g/mol, or weight average molecular weight of from about 3,000 to about 35,000 g/mol.

The epoxy resin composition (a) according to the present invention may further contain one or more additives such as fillers, dyes, pigments, thixotropic agents, surfactants, fluidity control agents, stabilizers, diluents that aid processing, adhesion promoters, flexibilizers, toughening agents and auxiliary flame retardants.

In the preparation of the epoxy resin composition of the present invention, the components are mixed together by known means in the art to form a curable composition, preferably in liquid form. The curable epoxy resin composition of the present invention can be produced by mixing all the components of the composition together in any order.

Preferably, the epoxy resin composition is in the form of a solution, wherein the components of the composition are dissolved in a solvent. Typically the metal phosphonate component is not soluble in common organic solvents. Therefore, the metal phosphonate needs to be dispersed in the epoxy resin composition using a powerful mechanical stirrer. In order to achieve uniform and stable dispersion it is important to have a metal phoshonate component with the average particle size in the range of from about 0.1 microns to about 3 microns. Such a solution or varnish is used for producing a prepreg.

As aforementioned, a neutral solvent may be employed in the blend of the epoxy resin composition to facilitate homogeneous mixing of the epoxy, curing agent, catalyst and metal phosphonate. The preferred optional solvent used in the present invention may include, for example, acetone and methyl ethyl ketone (MEK). In addition, any other suitable solvent can also be used provided it dissolves all of the components of the epoxy resin composition, excluding metal phosphonate.

Time and temperature of the process of forming the epoxy resin composition is not critical, but generally the components can be mixed at a temperature of from about 10° C. to about 60° C., preferably from about 20° C. to about 60° C. and more preferably from about 25° C. to about 40° C. for a sufficient time period until complete homogeneity is achieved.

The reinforcing material (b), which may be impregnated with the epoxy resin composition described herein, includes any material which would be used by the skilled artisan in formation of composites, prepregs and laminates. Examples of the forms of such reinforcing materials are woven fabric, cloth, mesh, web, or fibers, or in the form of a cross-ply laminate of unidirectionally oriented parallel filaments. Generally, such reinforcing materials are made from a variety of materials such as glass fibers, paper, plastics such as aromatic polyamides, graphite, glass, quartz, carbon, boron fibers, and organic fibers such as, for instance, aramid, teflon, syndiotactic polystyrene, and more particularly any reinforcing materials which is commonly used to make laminates for printed wiring boards. In one preferred embodiment, the reinforcing materials includes glass or fiberglass, in cloth or web form. As an illustration of the present application, the epoxy resin composition according to the disclosure herein is highly suitable for impregnating, for example, woven glass fabric.

In the preparation of a prepreg, a glass-cloth substrate impregnated with the epoxy resin composition is heated and dried to be semi-cured (B-stage state). A typical epoxy laminate B stage cure schedule involves heating impregnated cloth at for example from about 90° C. to about 210° C. for about 1 minute to about 10 minutes.

This prepreg can be employed to prepare a metal-clad laminate. First, metal foils such as the non-limiting example of copper (Cu)-foils are superimposed on at least one of opposite surfaces of the prepreg. Next, the resultant prepreg is heat-pressed for example from about 100° C. to about 230° C. for about 10 minutes to about 200 minutes under a pressure from about 50 psi to about 500 psi to give the metal-clad laminate. The metal-clad laminate may be prepared from only one prepreg or superposition of plural prepregs.

The metal-clad laminate can be employed in an article, e.g., to prepare a multi-layered printed wiring board. The multi-layered printed wiring board is formed with a conductor pattern by subtractive method or the like, for use as a core member. For example, the core member is formed at its opposite surfaces with metal foils (e.g., Cu-foils), and molded by heat-pressing, for preparation of the multi-layered printed wiring board.

The present invention is further illustrated by the Examples that follow.

### EXAMPLES

### Materials

Epoxy Resin, (PNE) phenol novolac epoxy, D.E.N. 438, brand of Dow Chemicals
Curing Agent 1 (DICY) dicyandiamide, Amicure CG-1200, brand of Air Products
Curing Agent 2, (PN) phenol novolac resin, Rezicure 3010H, brand of SI Group
Catalyst: (AMI-2) 2-methylimidazole, Imicure AMI-2, brand of Air Products
Flame Retardant 1 (AMMP) aluminum methyl methylphosphonate, experimental FR from ICL-IP
Flame Retardant 2 (HDP) hydroquinone bis(diphenyl phosphate), experimental FR from ICL-IP
Solvent: methylethyl ketone, (MEK), purchased from Fluka
Glass Cloth: 7628/50 style, product of BGF Industries
Copper Foil Gould Electronics Inc., (JTC, 1.0 oz./ft.²)

Preparation of the Varnish.

A weighted amount of epoxy resin was poured into a beaker equipped with a mechanical stirrer, a thermometer and a heating mantle. Then 25 p.h.r. of MEK was added at continuous stirring until a clear uniform solution was obtained. Then a weighted amount of curing agent PN or DICY was added. When PN was employed it dissolved and gave a clear solution whereas when DICY was employed it didn't dissolve, but formed a suspension. Then the weighted amount of AMMP or HDP was added and stirring was continued and when HDP was used the HDP dissolved and when AMMP was employed is formed a uniform white suspension. The catalyst was dissolved separately in methanol and added to the varnish composition last.

Manufacturing of Prepreg

A glass cloth (10.5×10.5 inch) was manually brushed on the both sides with the respective varnish at room temperature. Then it was squeezed with a roller to remove any excess varnish. The resultant impregnated glass cloth was placed in a preheated air circulated oven at 180° C. and exposed to the heat for 120-180 seconds. Experiments were repeated with different exposure times to find B-staging ensuring resin flow from about 10% to about 15% according to IPC-TM-650 test 2.3.16.2. Prepregs with resin content of about 40% were thus manufactured.

Manufacturing of Laminate

A stack of 8 prepregs prepared as indicated above with a copper foil on the bottom of the stack and on the top of the stack was placed between two stainless steel plates. Four sheets of Kraft paper were placed below and above the stainless steel plates. The entire assembly was placed in a hydraulic press which was linearly heated to 185° C. A pressure of 200 psi was applied at 170° C. The resultant laminates were cured at isothermal (185° C.) heating for 90 minutes.

Pressure Cooker Test

The copper was etched from above prepared laminates according to IPC-TM-650, test 2.3.7.1. A pressure cooker test (PCT) was performed according to IPC-TM 650, test 2.6.16 with the following modifications (a) specimens were exposed to the steam in autoclave for 0.5 or 2 hours; (b) the temperature of solder bath was held at 288° C., (c) the specimens were dipped in the solder for 20 seconds or 5 minutes.

Combustion Test

A combustion test was performed according to UL-94 vertical burn protocol.

Glass Transition Temperature (T_{g})

The glass transition temperature of each of the samples was measured by Differential Scanning Calorimetry (DSC) according to the IPC-TM 650, test 2.4.25

Table 1 below shows the concentrations of the components in the respective epoxy resin compostions and the physical properties and flammability of the resultant laminates

TABLE 1

| | | | | | Comparative |
|---|---|---|---|---|---|
| | Ex. 1 | Ex. 2 | Ex. 3 | Ex. 4 | Ex. 5 |
| Epoxy, wt. % | 75 | 70 | 65 | 60 | 75 |
| DICY, wt. % | 5 | 5 | 5 | | 5 |
| PN, wt. % | | | | 10 | |
| AMI-2, p.h.r. | 0.3 | 0.3 | 0.3 | 0.3 | 0.3 |
| AMMP, wt. % | 20 | 25 | 30 | 30 | |
| HDP, wt. % | | | | | 20 |
| UL-94 rating | V-1 | V-1 | V-0 | V-0 | Fail |
| PCT, 30 min | Pass | Pass | Pass | Pass | Fail |
| Water uptake, % | 0.33 | 0.26 | 0.27 | 0.28 | 0.28 |
| PCT, 2 h | | | Fail | Pass | |
| Water uptake, % | | | 0.54 | 0.51 | |
| T_{g}, (DSC), ° C. | 200 | 205 | 205 | 180 | 155 |

As it is seen from Table 1 epoxy composition containing 20 wt. % AMMP (Example 1) provided a UL-94 V-1 rating and passed the pressure cooker test (PCT) at min, which satisfies the minimal requirements for printed wiring boards. This formulation also provided a very high T_{g} of 200° C., which is very desirable in printed wiring boards. On the other hand, HDP added at the same level (Comparative example 5) failed the UL-94 and PCT tests and showed only a T_{g} of 155° C. Uses of higher levels of AMMP (in Examples 3 and 4) helped to pass the more stringent UL-94 V-0 requirement and further, the replacement of the DICY curing agent with PN (example 4) allowed for a pass of the PCT at 2 hours, followed by a 5 min dip into the solder.

Other embodiments of the invention will be apparent to those skilled in the art from a consideration of this specification or practice of the invention disclosed herein. It is intended that the specification and examples be considered as exemplary only, with the true scope and spirit of the invention being defined by the following claims.

1. An epoxy laminate comprising (a) an epoxy resin composition further comprising (i) at least one curable epoxy resin, (ii) at least one curing agent, (iii) at least one curing catalyst; and, (iv) a flame retardant effective amount of at least one metal phosphonate represented by the general formula: 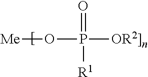
where Me is a metal, n is equal to the valency of the metal which is in the range of from 1 to 4, R¹ is a linear or branched alkyl of up to about 12 carbon atoms, R² is a linear or branched alkyl of up to about 12 carbon atoms or a substituted aryl or unsubstituted aryl of general formula: 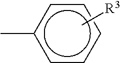
where R³ hydrogen, or a branched or linear alkyl of up to about 4 carbon atoms, or NH₂ or CN or NO₂,
(b) a reinforcing material; and, (c) a copper foil.

2. The epoxy laminate of claim 1, wherein Me is selected from the group consisting of Ca, Mg, Zn, Al, Fe, Ni, Cr, Ti.

3. The epoxy laminate of claim 1, wherein the metal phosphonate is metal salt of alkyl alkylphosphonic acid.

4. The epoxy laminate of claim 1, wherein the metal phosphonate is aluminum methyl methylphosphonate.

5. The epoxy laminate of claim 1 wherein the curable epoxy resin is present in an amount that ranges from about 40 to about 90 percent by weight of the total weight of the epoxy resin composition.

6. The epoxy laminate of claim 1 wherein the curable epoxy resin is present in an amount that ranges from about 60 to about 80 percent by weight of the total weight of the epoxy resin composition.

7. The epoxy laminate of claim 1 wherein the curing agent is selected from the following classes of compounds: polyamines, dicyandiamide, diaminodiphenylsulfone and their isomers, aminobenzoates, various acid anhydrides, phenol-novolac resins and cresol novolac resins.

8. The epoxy laminate of claim 1 wherein the curing agent is present in an amount that ranges from about 3 to about 30 percent by weight of the total weight of the epoxy resin composition.

9. The epoxy laminate of claim 1 wherein the curing agent is present in an amount that ranges from about 5 to about 20 percent by weight of the total weight of the epoxy resin composition.

10. The epoxy laminate of claim 1 wherein the catalyst is selected from the group consisting of alkaline metal compounds, alkaline earth metal compounds, imidazole compounds, secondary amine compounds, tertiary amine compounds, quaternary ammonium salts and quaternary phosphonium salts.

11. The epoxy laminate of claim 1 wherein the catalyst is present in an amount from about 0.01 to about 5 weight parts based on 100 weight parts of the epoxy resin composition including epoxy resin, curing agent and metal phosphonate (p.h.r.).

12. The epoxy laminate of claim 1 wherein the catalyst is present in an amount from about 0.05 to about 1.0 weight parts based on 100 weight parts of the epoxy resin composition including epoxy resin, curing agent and metal phosphonate (p.h.r.).

13. The epoxy laminate of claim 1 wherein the metal phosphonate is present in the range of from about 5 to about 40 percent by weight of the total weight of the epoxy resin composition.

14. The epoxy laminate of claim 1 wherein the metal phosphonate is present in the range of from about 15 to about 35 percent by weight of the total weight of the epoxy resin composition.

15. The epoxy laminate of claim 1 which can further include a poly(phenylene ether) thermoplastic component in the epoxy resin composition.

16. The epoxy laminate of claim 1 wherein the reinforcing agent is glass fiber cloth.

17. An article comprising the epoxy laminate of claim 1 wherein the article is a printed wiring board or a multilayer printed wiring board.
